(19) United States
(12) Patent Application Publication
(10) Pub. No.: US 2024/0170589 A1
(43) Pub. Date: May 23, 2024

(54) PHOTOELECTRIC SENSOR AND ELECTRONIC DEVICE

(71) Applicant: Shanghai Tianma Micro-Electronics Co., Ltd., Shanghai (CN)

(72) Inventors: Fan XU, Shanghai (CN); Bin ZHOU, Shanghai (CN); Haotian LU, Shanghai (CN); Kaidi ZHANG, Shanghai (CN); Linzhi WANG, Shanghai (CN); Zhen LIU, Shanghai (CN); Baiquan LIN, Shanghai (CN); Kerui XI, Shanghai (CN)

(73) Assignee: Shanghai Tianma Micro-Electronics Co., Ltd., Shanghai (CN)

(21) Appl. No.: 18/430,848

(22) Filed: Feb. 2, 2024

(30) Foreign Application Priority Data
Oct. 13, 2023 (CN) 202311330628.3

(51) Int. Cl. H01L 31/0232; H01L 27/144; H01L 31/113

(52) U.S. Cl. CPC H01L 31/02325; H01L 27/1446; H01L 31/1136

(57) ABSTRACT

Provided are a photoelectric sensor and an electronic device. The photoelectric sensor includes a substrate, a plurality of photoelectric sensing elements, and a wall structure between two adjacent photoelectric sensing elements. The wall structure includes a first layer and a second layer stacked with the first layer. The first layer is arranged at a side of the second layer away from the substrate and includes a light-blocking material. At least one of the first layer or the second layer of the wall structure is arranged in a same layer as at least one layer of the photoelectric sensing element.

### CROSS-REFERENCE TO RELATED DISCLOSURE

The present disclosure claims priority to Chinese Patent Application No. 202311330628.3, filed on Oct. 13, 2023, the content of which is incorporated herein by reference in its entirety.

### TECHNICAL FIELD

The present disclosure relates to the optical sensing field, and in particular, to a photoelectric sensor and an electronic device.

### BACKGROUND

A photoelectric sensor is an important element in various photoelectric detection systems and configured to convert a light signal to an electrical signal. Photoelectric sensors have the characteristics of non-contact, fast response speed, and reliable performance, and has been widely used in various electronic devices.

In operation, photoelectric sensors convert a received light signal to an electrical signal and then output the electrical signal. An interference between light signals may exist during the photoelectric conversion, causing a crosstalk to the generated electrical signal. As a result, the accuracy of the signal is reduced, and the reliability of the result outputted by the photoelectric sensor is reduced. It is important to solve the problem of interference between light signals in the photoelectric sensor.

### SUMMARY

In a first aspect, some embodiments of the present disclosure provide a photoelectric sensor. The photoelectric sensor includes a substrate, a plurality of photoelectric sensing elements arranged at a side of the substrate, and at least one wall structure. One wall structure of the at least one wall structure is located between two adjacent photoelectric sensing elements of the plurality of photoelectric sensing elements and includes a first layer and a second layer that are stacked together. The first layer is arranged at a side of the second layer away from the substrate and includes a light-blocking material. At least one of the first layer or the second layer of the wall structure is arranged in a same layer as at least one layer of one photoelectric sensing element of the plurality of photoelectric sensing elements.

In a second aspect, some embodiments of the present disclosure provide an electronic device. The electronic device includes a photoelectric sensor. The photoelectric sensor includes a substrate, a plurality of photoelectric sensing elements arranged at a side of the substrate, and at least one wall structure. One wall structure of the at least one wall structure is located between two adjacent photoelectric sensing elements of the plurality of photoelectric sensing elements and includes a first layer and a second layer that are stacked together. The first layer is arranged at a side of the second layer away from the substrate and includes a light-blocking material. At least one of the first layer or the second layer of the wall structure is arranged in a same layer as at least one layer of one photoelectric sensing element of the plurality of photoelectric sensing elements.

### DRAWINGS

In order to more clearly illustrate the technical solutions in the embodiments of the present disclosure, the accompanying drawings used in the description of the embodiments will be briefly introduced below. The accompanying drawings in the following description are only some embodiments of the present disclosure, and other drawings can be obtained by those of ordinary skill in the art from the provided drawings.

FIG. 1 is a schematic diagram of a photoelectric sensor according to some embodiments of the present disclosure;

FIG. 2 is another schematic diagram of a photoelectric sensor according to some embodiments of the present disclosure;

FIG. 3 is another schematic diagram of a photoelectric sensor according to some embodiments of the present disclosure;

FIG. 4 is another schematic diagram of a photoelectric sensor according to some embodiments of the present disclosure;

FIG. 5 is another schematic diagram of a photoelectric sensor according to some embodiments of the present disclosure;

FIG. 6 is another schematic diagram of a photoelectric sensor according to some embodiments of the present disclosure;

FIG. 7 is another schematic diagram of a photoelectric sensor according to some embodiments of the present disclosure;

FIG. 8 is another schematic diagram of a photoelectric sensor according to some embodiments of the present disclosure;

FIG. 9 is another schematic diagram of a photoelectric sensor according to some embodiments of the present disclosure;

FIG. 10 is a plan view of a photoelectric sensor according to some embodiments of the present disclosure;

FIG. 11 is another plan view of a photoelectric sensor according to some embodiments of the present disclosure;

FIG. 12 is another schematic diagram of a photoelectric sensor according to some embodiments of the present disclosure;

FIG. 13 is another schematic diagram of a photoelectric sensor according to some embodiments of the present disclosure;

FIG. 14 is another schematic diagram of a photoelectric sensor according to some embodiments of the present disclosure; and

FIG. 15 is a schematic diagram of an electronic device according to some embodiments of the present disclosure.

### DETAILED DESCRIPTION

In order to better understand technical solutions of the present disclosure, the embodiments of the present disclosure are described in detail with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in an embodiment of the present disclosure and the attached claims are also intended to include plural forms thereof, unless noted otherwise.

It should be understood that the term “and/or” used herein merely indicates a relationship describing associated objects, indicating three possible relationships. For example, the expression “A and/or B” indicates: A alone, both A and B, or B alone. In addition, the character “/” in this description generally means that the associated objects are in an “or” relationship.

In this specification, it should be understood that the terms “basically”, “approximately”, “roughly”, “about”, “generally” and “substantially” described in the claims and embodiments of this disclosure refer to a reasonable process operation range or tolerance range, which can be substantially agreed, rather than an exact value.

It should be understood that although the terms ‘first’, ‘second’ and ‘third’ can be used in the present disclosure to describe layers, directions and the like, these layers should not be limited to these terms. These terms are used only to distinguish layers from each other. For example, without departing from the scope of the embodiments of the present disclosure, a first layer can also be referred to as a second layer. Similarly, the second layer can also be referred to as the first layer.

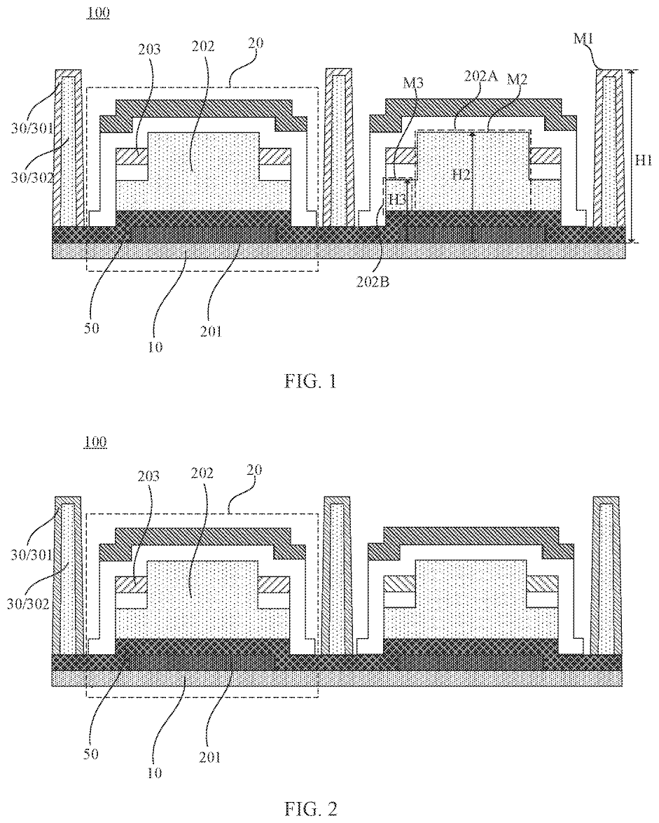

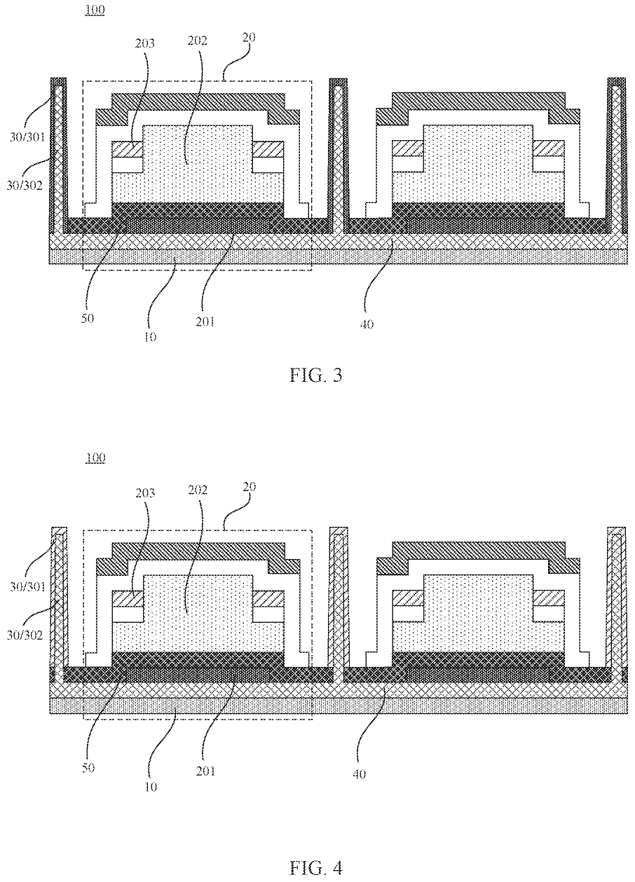

FIG. 1 is a schematic diagram of a photoelectric sensor according to some embodiments of the present disclosure. FIG. 2 is another schematic diagram of a photoelectric sensor according to some embodiments of the present disclosure. FIG. 3 is another schematic diagram of a photoelectric sensor according to some embodiments of the present disclosure.

Embodiments of the present disclosure provide a photoelectric sensor 100. As shown in FIG. 1 to FIG. 3, the photoelectric sensor 100 includes a substrate 10, photoelectric sensing elements 20 arranged at a side of the substrate 10, and at least one wall structure 30. The photoelectric sensing element 20 is configured to receive a light signal and convert a light signal to an electrical signal.

The wall structure 30 is located between two adjacent photoelectric sensing elements 20. The wall structure 30 includes a first layer 301 and a second layer 302 that are stacked together. In a direction perpendicular to a plane of the substrate 10, the first layer 301 is arranged at a side of the second layer 302 away from the substrate 10. In the fabricating process of the wall structure 30, the second layer 302 is formed, and then the first layer 301 is formed.

The first layer 301 of the wall structure 30 includes a light-blocking material. In some embodiments, the light-blocking material is metal. That is, the first layer 301 is not light transmissive, which can block light from passing through the wall structure 30.

In the fabricating process of the photoelectric sensor, at least one of the first layer 301 or the second layer 302 of the wall structure 30 is arranged in a same layer as at least one layer of the photoelectric sensing element 20.

In the fabricating process of the photoelectric sensor 100, one or two layers of the photoelectric sensing element 20 are formed simultaneously with the first layer 301 and/or the second layer 302 of the wall structure 30. When the first layer 301 and a layer of the photoelectric sensing element 20 are formed in the same layer, the first layer 301 of the wall structure 30 and a layer, made of a light-blocking material, of the photoelectric sensing element 20 are formed in the same layer.

When one of the first layer 301 and the second layer 302 of the wall structure 30 is formed in the same layer as a layer of the photoelectric sensing element 20, another one of the first layer 301 and the second layer 302 of the wall structure 30 may not formed in a same layer with any layer of the photoelectric sensing element 20 and is independently formed using another material.

In the related art, when light is incident on the photoelectric sensor, a single photoelectric sensing element may receive, in addition to the target light for this photoelectric sensing element, light reflected by other photoelectric sensing elements, so there is an interference between light signals of multiple photoelectric sensing elements. As a result, a crosstalk to the electrical signal of the photoelectric sensing element is caused, and the accuracy of the signal outputted by the photoelectric sensor is greatly reduced.

In the embodiments of the present disclosure, the wall structure 30 is provided between two adjacent photoelectric sensing elements 20. The first layer 301 of the wall structure 30 is formed by a light-blocking material, so the wall structure 30 has a reliable light-blocking characteristic. The wall structure 30 may block the reflected light between adjacent photoelectric sensing elements 20, avoids interference between light signals of adjacent photoelectric sensing elements 20, and ensures the accuracy of the signal transmitted by the photoelectric sensor.

At least one of the first layer 301 and the second layer 302 of the wall structure 30 is arranged in a same layer as at least one layer of the photoelectric sensing element 20. Therefore, in the fabricating process of the photoelectric sensor 100, at least one layer of the wall structure 30 does not need to be formed individually, simplifying the fabricating process, reducing the number of masks used for fabricating the photoelectric sensor 100, and reducing fabricating cost.

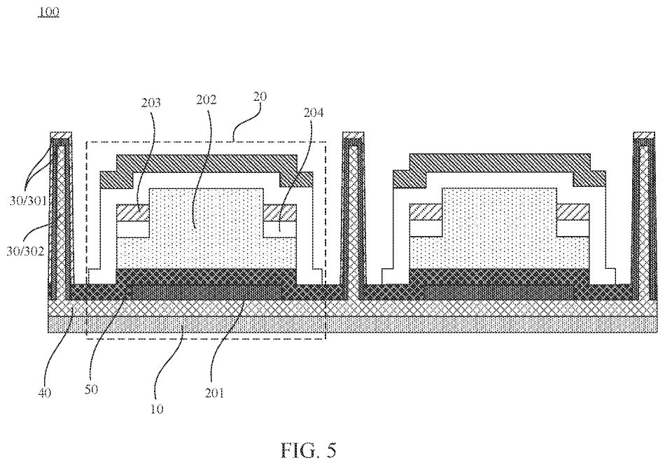

FIG. 4 is another schematic diagram of a photoelectric sensor according to some embodiments of the present disclosure. FIG. 5 is another schematic diagram of a photoelectric sensor according to some embodiments of the present disclosure.

In some embodiments, as shown in FIG. 1 to FIG. 5, the photoelectric sensing element 20 includes a first gate electrode 201, an active layer 202, and source and drain electrodes 203. The source and drain electrodes 203 include a source electrode and drain electrode of the photoelectric sensing element 20. The active layer 202 of the photoelectric sensing element 20 may be formed by amorphous silicon. The first gate electrode 201 and the source and drain electrodes 203 may be made of metal.

The first gate electrode 201 of the photoelectric sensing element 20 is located at a side of the active layer 202 close to the substrate 10. The source and drain electrodes 203 are located at a side of the active layer 202 away from the substrate 10. Thus, in the fabricating process of the photoelectric sensing element 20, the first gate electrode 201 is formed, then the active layer 202 is formed, and then the source and drain electrodes 203 are formed.

The first layer 301 of the wall structure 30 is formed in a same layer as at least one of the first gate electrode 201 or the source and drain electrodes 203.

In some embodiments, as shown in FIG. 1 and FIG. 4, the first layer 301 of the wall structure 30 and the source and drain electrodes 203 of the photoelectric sensing element 20 are formed in the same layer.

In some embodiments, as shown in FIG. 3, the first layer 301 of the wall structure 30 and the first gate electrode 201 of the photoelectric sensing element 20 are formed in the same layer.

In some embodiments, as shown in FIG. 5, the first layer 301 of the wall structure 30 is a composite layer, at least one sub-layer of the composite layer is formed in the same layer as the first gate electrode 201 of the photoelectric sensing element 20, and at least another one sub-layer 20 of the composite layer is formed in the same layer as the source and drain electrodes 203 of the photoelectric sensing element 20.

When the second layer 302 of the wall structure 30 is formed in a same layer as a layer of the photoelectric sensing element 20 (as shown in FIG. 2, the second layer 302 of the wall structure 30 and active layer 202 of the photoelectric sensing element 20 are formed in a same 25 layer), the first layer 301 of the wall structure 30 may be formed separately. In this way, the fabricating process is simplified, the light-blocking material for making the first layer 301 can be flexibly adjusted, and the structure of the wall structure 30 can be flexibly adjusted according to different light-blocking requirements, which improves the light-blocking reliability of the wall structure 30.

In some embodiments, the first gate electrode 201 and the source and drain electrodes 203 of the photoelectric sensing element 20 are made of metal, and then the first layer 301 is made of the same material as the first gate electrode 201 and/or the source and drain electrodes 203 when the first layer 301 of the wall structure 30 is formed in the same layer as at least one of the first gate electrode 201 or the source and drain electrodes 203, so the first layer 301 can block light. In this way, the light-blocking function of the wall structure 30 can be realized, and it is avoided that the reflected light between adjacent photoelectric sensing elements 20 affect each other.

As shown in FIG. 5, the first layer 301 of the wall structure 30 is a composite layer, that is, at least one sub-layer of the first layer 301 of the wall structure 30 is formed in a same layer as the first gate electrode 201 and at least another one sub-layer of the first layer 301 is formed in the same layer as the source and drain electrodes 203, which improves the light-blocking effect of the first layer 301 without adding process steps. With such configuration, the height of the wall structure 30 can be flexibly designed, and the light-blocking reliability of the wall structure 30 is improved, which improves the performance reliability of the photoelectric sensor 100.

In some embodiments of the present disclosure, as shown in FIG. 1, the second layer 302 of the wall structure 30 and the active layer 202 are formed in the same layer, and the first layer 301 of the wall structure 30 and the source and drain electrodes 203 of the photoelectric sensing element 20 are formed in a same layer.

In some embodiments, the first layer 301 and the second layer 302 of the wall structure are formed in a same layer as a layer of the photoelectric sensing element 20. In this way, the height of the wall structure 30 and the height of the active layer 202 of the photoelectric sensing element 20 are formed at similar levels. While realizing light-blocking function of the wall structure 30, the fabricating processes of the photoelectric sensor 100 can be reduced, thereby improving the fabricating efficiency, and reducing the fabricating cost.

In other embodiments of the present disclosure, as shown in FIG. 3 to FIG. 5, in the photoelectric sensor 100, a first insulation layer 40 is provided at a side of the first gate electrode 201 close to the substrate 10, and the second layer 302 of the wall structure 30 and the first insulation layer 40 are formed in a same layer.

In some embodiments, the first insulation layer 40 is formed at a side of substrate 40, and the second layer 302 of the wall structure 30 is formed simultaneously. After the first insulation layer 40 is formed, the first gate electrode 201 is formed at a side of the first insulation layer 40 away from the substrate 10, that is, the layers of the photoelectric sensing element 20 are formed after the first insulation layer 40 is formed.

In this case, the first layer 301 of the wall structure 30 may be formed in a same layer as at last one of the first gate electrode 201 or the source and drain electrodes 203 of the photoelectric sensing element 20.

For example, as shown in FIG. 3, the second layer 302 of the wall structure 30 and the first insulation layer 40 are located in a same layer, and the first layer 301 and the first gate electrode 201 are located in a same layer. As shown in FIG. 4, the second layer 302 of the wall structure 30 and the first insulation layer 40 are located in the same layer, and the first layer 301 and the source and drain electrodes 203 are located in a same layer. As shown in FIG. 5, the second layer 302 of the wall structure 30 and the first insulation layer 40 are located in a same layer, at least one sub-layer of the first layer 301 and the first gate electrode 201 are located in a same layer, and at least another sub-layer of the first layer 301 and the source and drain electrodes 203 are located in a same layer.

In the embodiments of the present disclosure, the second layer 302 of the wall structure 30 and the first insulation layer 40 are formed in the same layer, so the height of the second layer 302 can be flexibly designed according to the height requirement of the wall structure 30. In this way, the first layer 301 arranged on the second layer 302 has a larger light-blocking range, the wall structure 30 provides an improved blocking effect on the reflected light between two adjacent photoelectric sensing elements 20, and the accuracy of receiving the light signal of the photoelectric sensing element 20 is improved.

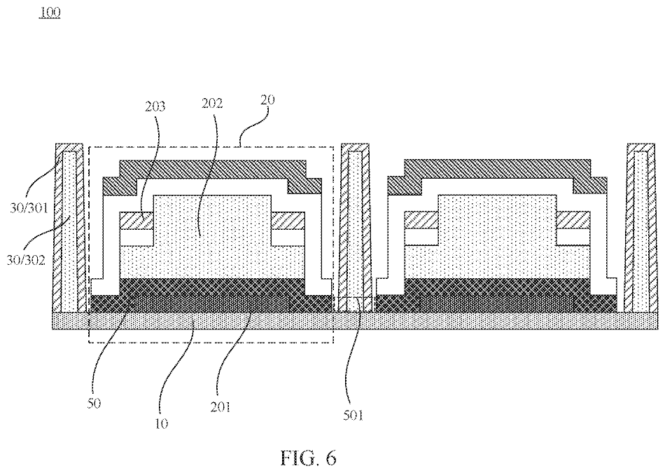

FIG. 6 is another schematic diagram of a photoelectric sensor according to some embodiments of the present disclosure.

In some embodiments of the present disclosure, as shown in FIG. 1 to FIG. 6, the photoelectric sensor 100 includes a gate insulation layer 50. At least part of the gate insulation layer 50 is located between the first gate electrode 201 and the active layer 202 and is configured to prevent the active layer 202 from being electrically connected to the first gate electrode 201.

As shown in FIG. 6, the gate insulation layer 50 includes a first opening 501, and the wall structure 30 is located in the first opening 501. That is, the gate insulation layer 50 is disconnected at the wall structure 30.

The gate insulation layer 50 generally is a light-transmitting layer. In some embodiments of the present disclosure, the wall structure 30 is formed in the first opening 501 of the gate insulation layer 50. In this way, the reflected light is prevented from entering the active layer 202 of the adjacent photoelectric sensing element 20 via the gate insulation layer 50, a reliability of the blocking the reflected light of the wall structure 30 is improved, and the accuracy of transmitting signal by the photoelectric sensor 100 is ensured.

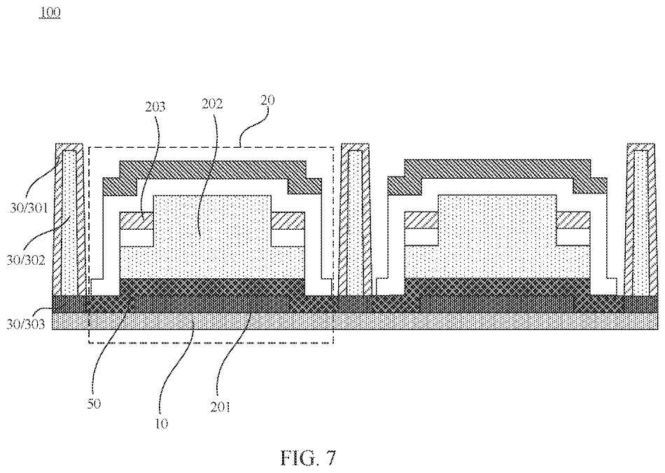

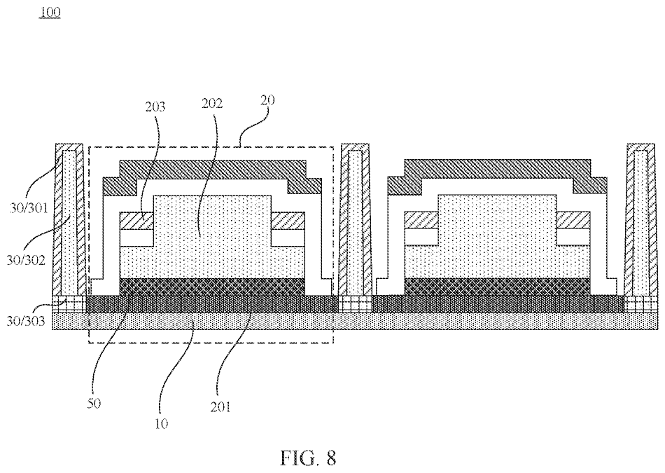

FIG. 7 is another schematic diagram of a photoelectric sensor according to some embodiments of the present disclosure. FIG. 8 is another schematic diagram of a photoelectric sensor according to some embodiments of the present disclosure.

In some embodiments of the present disclosure, as shown in FIG. 7, the wall structure 30 includes a third layer 303. The third layer 303 is located at a side of the second layer 302 close to the substrate 10, and the third layer 303 and the first gate electrode 201 are located in a same layer.

In this case, the first layer 301 of the wall structure 30 and the source and drain electrodes 203 of the photoelectric sensing element 20 may be formed in a same layer, and the second layer 302 of the wall structure 30 and the active layer 202 of the photoelectric sensing element 20 may be formed in a same layer.

In some other embodiments, as shown in FIG. 8, the third layer 303 of the wall structure 30 may be made of a light-blocking material different from the material of the first gate electrode 201 of the photoelectric sensing element 20.

In some embodiments of the present disclosure, the wall structure 30 includes the third layer 303, so the height of the wall structure 30 can be flexibly adjusted according to the light-blocking requirement of the wall structure 30. The third layer 303 and the first gate electrode 201 of the photoelectric sensing element 20 are arranged in the same layer without an additional process of forming the third layer 303, which reduces the fabricating cost of the photoelectric sensor 100.

In some embodiments, since the first gate electrode 201 includes metal, the third layer 303 of the wall structure 30 also has the light-blocking characteristic. Light reflected by the photoelectric sensing element 20 is prevented from entering, at a position below the wall structure 30, the active layer 202 of the adjacent photoelectric sensing element 20, so a reliability of blocking light of the wall structure 30 is improved.

When the third layer 303 and the first gate electrode 201 are formed in a same layer, as shown in FIG. 7, the third layer 303 and the first gate electrode 201 are insulated from each other.

In some embodiments, as shown in FIG. 7, when the third layer 303 of the wall structure 30 and the first gate electrode 201 are formed in a same layer, the third layer 303 is located in a gap between two adjacent first gate electrodes 201, and the third layer 303 is not connected to the two first gate electrodes 201 adjacent to the third layer 303. In this way, the third layer 303 is electrically insulated from the first gate electrodes 201.

When the first gate electrodes 201 of two adjacent photoelectric sensing elements 20 are electrically connected to each other through a connection line, the third layer 303 of the wall structure 30 and the connection line are spaced apart from each other, to electrically insulate the third layer 303 from the first gate electrode 201.

In this way, on the one hand, it is avoided that the first gate electrode 201 and the third layer 301 are connected into one piece, which avoids an increase of the power of the signal supplied to the first gate electrode 201. On the other hand, it is avoided that the first gate electrodes 201 receiving different signals are connected to each other via the third layer 303, which avoids affecting the normal operation of the photoelectric sensor.

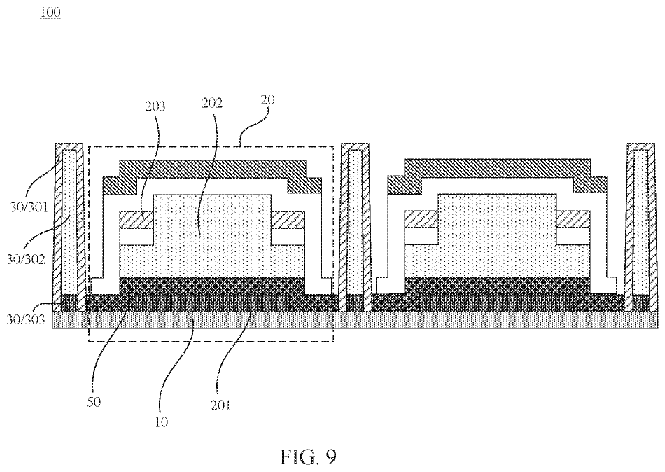

FIG. 9 is another schematic diagram of a photoelectric sensor according to some embodiments of the present disclosure.

In some embodiments of the present disclosure, as shown in FIG. 7 and FIG. 9, the first layer 301 and the third layer 303 of the wall structure 30 are in contact with each other and connected to each other. That is, in a same wall structure 30, the first layer 301 may extend onto the third layer 303.

In some embodiments, as shown in FIG. 7, in the wall structure 30, the first layer 301 extends onto a surface of the third layer 303 away from the substrate 10.

In some embodiments, as shown in FIG. 9, in the wall structure 30, the first layer 301 extends onto a side surface of the third layer 303.

In the embodiments of the present disclosure, the first layer 301 and the third layer 303 of the wall structure 30 are in contact with each other and connected to each other, so the first layer 301 and the third layer 303 both having the light-blocking function are connected into one piece. In this way, the light reflected by the photoelectric sensing element 20 is prevented from entering the active layer 202 of the adjacent photoelectric sensing element 20 via the gap between the first layer 301 and the third layer 303, thereby improving a reliability of blocking light of the wall structure 30, and preventing interference between the light signals of adjacent photoelectric sensing elements 20.

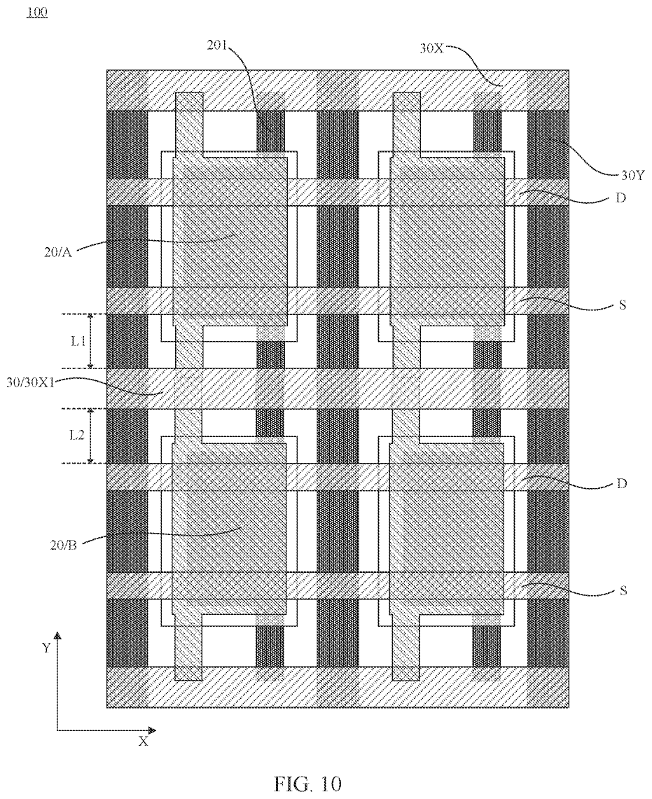

FIG. 10 is a plan view of a photoelectric sensor according to some embodiments of the present disclosure.

In some embodiments of the present disclosure, as shown in FIG. 10, photoelectric sensing elements 20 are arranged in a matrix, at least two photoelectric sensing elements 20 are arranged in a first direction Y, and at least two photoelectric sensing elements 20 are arranged in a second direction X crossing the first direction Y. The source electrodes S of two or more photoelectric sensing elements 20 arranged in the second direction X are electrically connected to each other, and the drain electrodes D of two or more photoelectric sensing elements 20 arranged in the second direction X are electrically connected to each other. The source electrode S and the drain electrode D are located in a same layer, and are the source and drain electrodes 203 of the photoelectric sensing element 20, respectively.

The source electrodes S of the photoelectric sensing elements 20 arranged in the second direction X are connected to each other to form an integral part extending in the second direction X, and the drain electrodes D of the photoelectric sensing elements 20 arranged in the second direction X are connected to each other to form an integral part extending in the second direction X. The source electrode S and the drain electrode D of the photoelectric sensing element 20 may be parallel to each other.

In some embodiments, as shown in FIG. 10, the wall structures 30 include first wall structures 30Y and second wall structures 30X. The first wall structures 30Y are arranged in the second direction X, and the first wall structure 30Y extends in the first direction Y. The second wall structures 30X are arranged in the first direction Y, and the second wall structure 30X extends in the second direction X.

The first layer 301 of the first wall structure 30Y and the first gate electrode 201 of the photoelectric sensing element 20 are located in a same layer, and the first layer 301 of the second wall structure 30X and the source and drain electrodes 203 of the photoelectric sensing element 20 are located in a same layer.

In this case, the second layer 302 of the first wall structure 30Y and the first insulation layer 40 are formed in a same layer. The second layer 302 of the second wall structure 30X and the first insulation layer 40 are formed in a same layer, and is also formed in a same layer as the active layer 202 of the photoelectric sensing element 20.

The source electrode S and the drain electrode D of the photoelectric sensing element 20 both extending in the second direction X may cross the first wall structure 30Y extending in the first direction Y. In the embodiments of the present disclosure, the first layer 301 of the first wall structure 30Y and the first gate electrode 201 of the photoelectric sensing element 20 are formed in the same layer, which prevents the first wall structure 30Y from being electrically connected to the source electrode S and the drain electrode D of the photoelectric sensing element 20. In this way, short-circuit between the source electrode S and the drain electrode D of the photoelectric sensing element 20 via the first wall structure 30Y is avoided, ensuring the normal operation of the photoelectric sensor.

The first layer 301 of the second wall structure 30X and the source and drain electrodes 203 of the photoelectric sensing element 20 are formed in a same layer, so the second wall structure 30X has greater diversity, and the structure of the photoelectric sensor 100 has greater diversity.

In some other embodiments, the first layer 301 of the second wall structure 30X and the first gate electrode 201 of the photoelectric sensing element 20 may be formed in a same layer.

In some embodiments of the present disclosure, as shown in FIG. 10, the second wall structure 30X is provided between two photoelectric sensing elements 20 adjacent to each other in the first direction Y, and the second wall structure 30X extends in the second direction X. The source electrode S of one of the two adjacent photoelectric sensing elements 20 is adjacent to the second wall structure 30X, and the drain electrode of another one of the two adjacent photoelectric sensing elements 20 is adjacent to the second wall structure 30X.

A minimum distance L1 between the second wall structure 30X and the source electrode S is equal to a minimum distance L2 between the second wall structure 30X and the drain electrode D. That is, the second wall structure 30X is located in the middle of the two adjacent photoelectric sensing elements 20.

For example, as shown in FIG. 10, two photoelectric sensing elements 20 adjacent to each other in the first direction Y are a photoelectric sensing element A and a photoelectric sensing element B, respectively, and the second wall structure between the photoelectric sensing element A and the photoelectric sensing element B is the second wall sub-structure 30X1. The source electrode S of the photoelectric sensing element A is adjacent to the second wall sub-structure 30X1, and the drain electrode D of the photoelectric sensing element B is adjacent to the second wall sub-structure 30X1.

The minimum distance between the second wall sub-structure 30X1 and the source electrode S of the photoelectric sensing element A is L1, and the minimum distance between the second wall sub-structure 30X1 and the drain electrode D of the photoelectric sensing element B is L2, where L1=L2.

In the second direction X, the first wall structure 30Y may be arranged in the middle of two photoelectric sensing elements 20 adjacent to the first wall structure 30Y.

In some embodiments of the present disclosure, the second wall structure 30X is arranged in the middle of the two photoelectric sensing elements 20 adjacent to the second wall structure 30X. In this way, reasonable space allocation is realized in the fabricating process of the photoelectric sensor 100, the layout difficulty of the wall structures 30 and the photoelectric sensing elements 20 in the photoelectric sensor is reduced, and the space utilization of the photoelectric sensor 100 is improved.

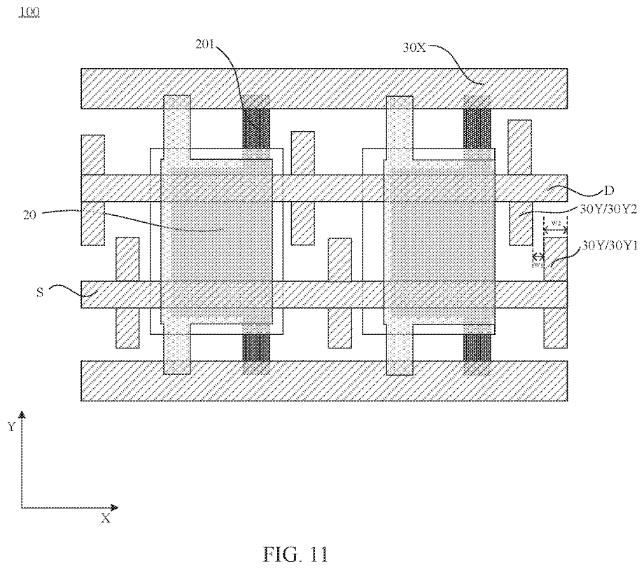

FIG. 11 is a plan view of another photoelectric sensor according to some embodiments of the present disclosure.

In some embodiments of the present disclosure, as shown in FIG. 11, the first layer 301 of the wall structure 30 and the source and drain electrodes 203 of the photoelectric sensing element 20 are located in a same layer.

The wall structures 30 include first wall structures 30Y arranged in the second direction X. The first wall structure 30Y includes a first part 30Y1 and a second part 30Y2. The first layer 301 of the first wall structure 30Y at the first part 30Y1 is electrically connected to the source electrode S of the photoelectric sensing element 20 adjacent to the first part 30Y1, and the first part 30Y1 extends in the first direction Y.

The first layer 301 of the first wall structure 30Y at the second part 30Y2 is electrically connected to the drain electrode D of the photoelectric sensing element 20 adjacent to the second part 30Y2, and the second part 30Y2 extends in the first direction Y. The first wall structure 30Y formed by the first part 30Y1 and the second part 30Y2 extends in the first direction Y.

The first part 30Y1 and the second part 30Y2 are spaced apart from each other in the first direction Y and/or the second direction X. That is, the first part 30Y1 connected to the source electrode S and the second part 30Y2 connected to the drain electrode D are electrically insulated from each other.

In some embodiments of the present disclosure, the first layer 301 of the wall structure 30 and the source and drain electrodes 203 of the photoelectric sensing element 20 are formed in a same layer, so the second layer 302 of the wall structure 30 and the active layer 202 of the photoelectric sensing element 20 may be formed in a same layer, simplifying the fabricating process of the photoelectric sensor 100.

Since the source electrode S and the drain electrode D of the photoelectric sensing element 20 each extend in the second direction X, the first wall structure 30Y extending in the first direction Y includes the first part 30Y1 and the second part 30Y2, and the first part 30Y1 and the second part 30Y2 are spaced apart from each other. That is, the first wall structure 30Y is discontinuous in the first direction Y. Therefore, it is avoided that the first wall structure 30Y crosses and is electrically connected to the source electrode S and the drain electrode D, and the short-circuit between the source electrode S and the drain electrode D of the photoelectric sensing element 20 is avoided.

The second wall structures 30X arranged in the first direction Y each extend in the second direction X, and are continuous in the second direction X.

In some embodiments of the present disclosure, as shown in FIG. 11, the first part 30Y1 and the second part 30Y2 are spaced apart from each other in the second direction X, and the first part 30Y1 and the second part 30Y2 overlap each other in the second direction X.

In the embodiments, the first part 30Y1 and the second part 30Y2 are spaced apart from each other so as to prevent the first part 30Y1 from being electrically connected to the second part 30Y2, which avoids the short-circuit between the source electrode S and the drain electrode D of the photoelectric sensing element 20.

The first part 30Y1 and the second part 30Y2 overlap each other in the second direction X, so the first part 30Y1 and the second part 30Y2, as a whole, has no gap in the first direction Y, and the reflected light traveling in the second direction X can be blocked by the first part 30Y1 and the second part 30Y2 jointly. In this way, while ensuring the normal operation of the photoelectric sensing element 20, the interference of the reflected light between adjacent photoelectric sensing elements 20 is avoided.

In some embodiments of the present disclosure, as shown in FIG. 11, in the second direction X, a width W1 of a gap between the first part 30Y1 and the second part 30Y2 and a width W2 of the first part 30Y1 satisfy 4 μm≤W1≤W2. The first part 30Y1 and the second part 30Y2 may have an equal width.

In some embodiments, in the second direction X, the width of the gap between the first part 30Y1 and the second part 30Y2 is set in a preset range. In this way, it can be avoided that the width W1 of the gap between the first part 30Y1 and the second part 30Y2 is too small to increase the fabricating difficulty, and it can also be avoided that a small distance between the first part 30Y1 and the second part 30Y2 causes unreliability of the electrical insulation between the first part 30Y1 and the second part 30Y2. Such configuration also avoids that a large coupling capacitance between the first part 30Y1 and the second part 30Y2 affects the operation stability of the photoelectric sensing element 20.

With the configuration where the width of the gap between the first part 30Y1 and the second part 30Y2 is set in the preset range, it can be avoided that an excessively large distance between two photoelectric sensing elements 20 adjacent in the second direction X reduces a density of the photoelectric sensing elements 20, which ensures the operation precision of the photoelectric sensor 100.

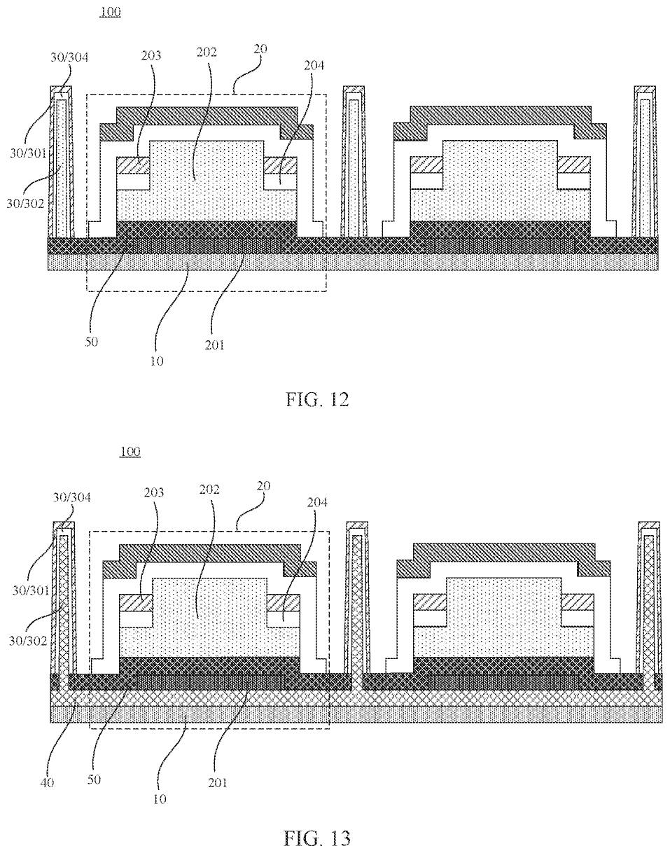

FIG. 12 is another schematic diagram of a photoelectric sensor according to some embodiments of the present disclosure. FIG. 13 is another schematic diagram of a photoelectric sensor according to some embodiments of the present disclosure.

In some embodiments, as shown in FIG. 12 and FIG. 13, the photoelectric sensing element 20 includes a connection layer 204 located at a side of the source and drain electrodes 203 close to the active layer 202.

For example, the connection layer 204 may be arranged between the source and drain electrodes 203 and the active layer 204, and the connection layer 204 may include an N-type doped semiconductor. After the active layer 202 is formed, the connection layer 204 is formed.

The wall structure 30 can include a fourth layer 304 located between the first layer 301 and the second layer 302, and the fourth layer and the connection layer 204 are located in a same layer.

In some embodiments, as shown in FIG. 12, the first layer 301 of the wall structure 30 and the source and drain electrodes 203 of the photoelectric sensing element 20 may be formed in a same layer, and the second layer 302 of the wall structure 30 and the active layer 202 of the photoelectric sensing element 20 may be formed in a same layer.

In some embodiments, as shown in FIG. 13, the first layer 301 of the wall structure 30 and the source and drain electrodes 203 of the photoelectric sensing element 20 may be formed in a same layer, and the second layer 302 of the wall structure 30 and the first insulation layer 40 of the photoelectric sensing element 20 may be formed in a same layer.

In the embodiments of the present disclosure, since the wall structure 30 includes the fourth layer 304, the height of the wall structure 30 can be flexibly adjusted according to the light-blocking requirements of the wall structure 30. In this way, the reliability of light-blocking of the wall structure 30 is improved, and the usability of the wall structure 30 is improved.

The fourth layer 304 and the connection layer 204 of the photoelectric sensing element 20 are formed in a same layer without an additional process of forming the fourth layer 304, thereby avoiding an increase in the fabricating cost of the photoelectric sensor 100.

In some embodiments of the present disclosure, as shown in FIG. 1, the first layer 301 of the wall structure 30 includes a first surface M1 away from the substrate 10, and a distance between the first surface M1 and the substrate 10 is H1. The active layer 202 of the photoelectric sensing element 20 includes a middle part 202A and an edge part 202B, and a thickness of the middle part 202A is greater than a thickness of the edge part 202B. A difference in height between the middle part 202A and the edge part 20B of the photoelectric sensing element 20 is beneficial to increase a collect speed of carriers, which improves the electrical performance of the photoelectric sensing element 20.

The middle part 202A of the active layer 202 includes a second surface M2 away from the substrate 10, and a distance between the second surface M2 and the substrate 10 is H2, and H1≥H2.

In the embodiments of the present disclosure, since the distance H1 between the first surface M1 of the wall structure 30 and the substrate 10 is greater than the distance H2 between the second surface M2 of the photoelectric sensing element 20 and the substrate 10, it is ensured that the wall structure 30 can prevent the reflected light from being incident to the active layer 202 of the adjacent photoelectric sensing element 20, thereby ensuring the reliability of the light-blocking effect of the wall structure 30.

In some embodiments of the present disclosure, H1-H2≤1 μm. That is, the height difference between the wall structure 30 and the active layer 202 is not too large.

In the embodiments of the present disclosure, since the difference between the distance H1 between the first surface M1 of the wall structure 30 and the substrate 10 and the distance H2 between the second surface M2 of the photoelectric sensing element 20 and the substrate 10 is set within a preset range, a steep slope formed when layers pass the wall structure 30 after the formation of the active layer 202 is avoided, which can avoid fractures of these layer at the wall structure 30, ensure the reliability of layers of the photoelectric sensor 100, and improve the product reliability of the photoelectric sensor 100.

In some embodiments of the present disclosure, as shown in FIG. 1, the edge part 202B includes a third surface M3 away from the substrate 10, and a distance H3 between the third surface M3 and the substrate 10 satisfies:

$$\frac{H 1 - H 2}{H 2} < \frac{H 2 - H 3}{H 3} .$$

In the embodiments, with the configuration where H1, H2, and H3 satisfy the above relationship, the height of the wall structure 30 can be flexibly designed according to the heights of the middle part 202A and the edge part 202B of the active layer 202. In this way, structural parameters of the wall structure 30 can be adaptability adjusted according to structural parameters of the photoelectric sensing element 20 so that the height of the wall structure 30 is within the preset range. While ensuring the blocking effect to the reflected light, it is avoided that a fracture of the layer formed when the layer passes the wall structure 30 after the formation of the active layer 202, thereby improving the product reliability of the photoelectric sensor 100.

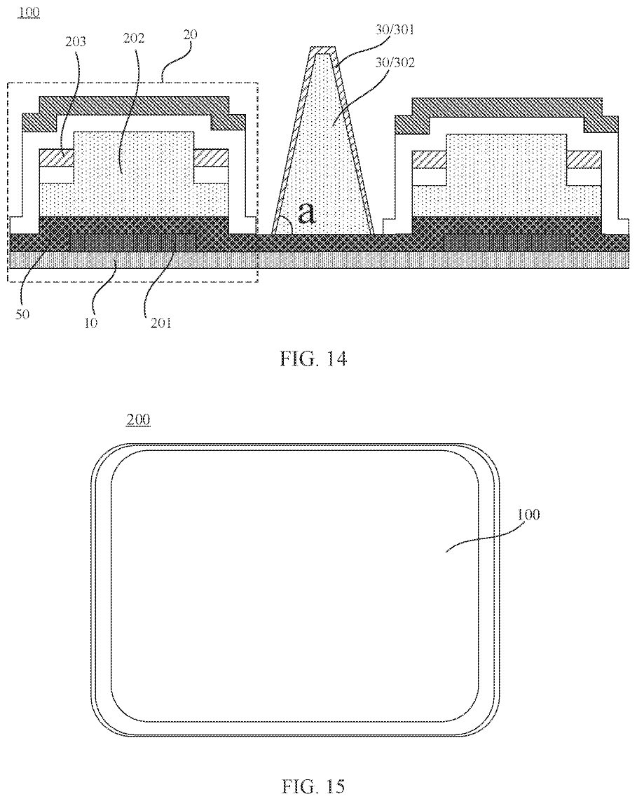

FIG. 14 is another schematic diagram of a photoelectric sensor according to some embodiments of the present disclosure.

In some embodiments of the present disclosure, as shown in FIG. 14, an included angle a between a side surface 302A of the second layer 302 of the wall structure 30 and a plane of the substrate 10 satisfies 40°≤a≤50°.

In the embodiments of the present disclosure, since the included angle a between the plane of the substrate 10 and a side surface 302A of the second layer 302 of the wall structure 30 is set within a preset range, the height of the second layer 302 is ensured, and it is also avoided that the side surface of the second layer 302 is too steep. When the first layer 301 is formed on the second layer 302, a fracture of the first layer 301 is avoided, thereby ensuring the light-blocking range of the first layer 301 and ensuring the light-blocking effect of the wall structure 30.

FIG. 15 is a schematic diagram of an electronic device according to some embodiments of the present disclosure.

Some embodiments of the present disclosure provide an electronic device 200. As shown in FIG. 15, the electronic device 200 includes the photoelectric sensor 100 provided in the above embodiments. The electronic device 200 may be a radiographic image detector, a video camera, a mobile phone camera, and the like.

In the electronic device 200, the wall structure 30 is arranged between two adjacent photoelectric sensing elements 20. The first layer 301 of the wall structure 30 is made of a light-blocking material, so the wall structure 30 has a reliable light-blocking effect. The wall structure 30 can block the reflected light between adjacent photoelectric sensing elements 20, so the interference between light signals of adjacent photoelectric sensing elements 20 is avoided, and the accuracy of the signal transmitted by the photoelectric sensor 100 is ensured.

At least one of the first layer 301 or the second layer 302 of the wall structure 30 is arranged in a same layer as at least one layer of the photoelectric sensing element 20. Therefore, in the fabricating process of the photoelectric sensor 100, at least one layer of the wall structure 30 does not need to be formed individually, simplifying the fabricating process, reducing the number of masks used for fabricating the photoelectric sensor 100, and reducing fabricating cost.

The above are merely exemplary embodiments of the present disclosure, and are not intended to limit the present disclosure. Any modification, equivalent replacement, improvement and the like within the principle of the present disclosure all fall within the scope of the present disclosure.

What is claimed is:

1. A photoelectric sensor, comprising:
a substrate;
a plurality of photoelectric sensing elements arranged at a side of the substrate; and
at least one wall structure,
wherein one wall structure of the at least one wall structure is located between two adjacent photoelectric sensing elements of the plurality of photoelectric sensing elements and comprises a first layer and a second layer that are stacked together, wherein the first layer is arranged at a side of the second layer away from the substrate and comprises a light-blocking material; and
wherein at least one of the first layer or the second layer of the wall structure is arranged in a same layer as at least one layer of one photoelectric sensing element of the plurality of photoelectric sensing elements.

2. The photoelectric sensor of claim 1, wherein the photoelectric sensing element comprises a first gate electrode, an active layer, a source electrode, and a drain electrode, wherein the first gate electrode is arranged at a side of the active layer close to the substrate, and the source electrode and the drain electrode are arranged at a side of the active layer away from the substrate; and
wherein the first layer of the wall structure is arranged in a same layer as at least one of the first gate electrode, the source electrode, or the drain electrode.

3. The photoelectric sensor of claim 2, wherein the second layer of the wall structure is arranged in a same layer as the active layer.

4. The photoelectric sensor of claim 2, further comprising:
a first insulation layer arranged at a side of the first gate electrode close to the substrate, wherein the second layer of the wall structure is arranged in a same layer as the first insulation layer.

5. The photoelectric sensor of claim 3, wherein the photoelectric sensing element further comprises a gate insulation layer, wherein at least part of the gate insulation layer is arranged between the first gate electrode and the active layer, the gate insulation layer comprises a first opening in which one wall structure of the at least one wall structure is located.

6. The photoelectric sensor of claim 3, wherein the wall structure further comprises a third layer arranged at a side of the second layer close to the substrate and arranged in a same layer as the first gate electrode.

7. The photoelectric sensor of claim 6, wherein the third layer is electrically insulated from the first gate electrode.

8. The photoelectric sensor of claim 6, wherein the first layer and the third layer of the wall structure are in contact with each other and connected to each other.

9. The photoelectric sensor of claim 2, wherein the plurality of photoelectric sensing elements is arranged in a matrix, wherein at least two photoelectric sensing elements of the plurality of photoelectric sensing elements are arranged in a first direction, and at least two photoelectric sensing elements of the plurality of photoelectric sensing elements are arranged in a second direction crossing the first direction, and
wherein the source electrodes of two or more photoelectric sensing elements of the at least two photoelectric sensing elements arranged in the second direction are electrically connected to each other, and the drain electrodes of two or more photoelectric sensing elements of the at least two photoelectric sensing elements arranged in the second direction are electrically connected to each other.

10. The photoelectric sensor of claim 9, wherein the first layer of the wall structure is arranged in a same layer as the source electrode and the drain electrode of the photoelectric sensing element, and the at least one wall structure comprises a plurality of first wall structures arranged along the second direction; and
wherein one first wall structure of the plurality of first wall structures comprises a first part and a second part, the first layer of the first wall structure of at the first part is electrically connected to the source electrode of one photoelectric sensing element of the plurality of photoelectric sensing elements adjacent to the first part, and the first layer of the first wall structure of at the second part is electrically connected to the drain electrode of one photoelectric sensing element of the plurality of photoelectric sensing elements adjacent to the second part, and
wherein the first part and the second part are spaced apart from each other in at least one of the first direction or the second direction.

11. The photoelectric sensor of claim 10, wherein the first part and the second part are spaced apart from each other in the second direction, and overlap each other in the second direction.

12. The photoelectric sensor of claim 11, wherein a gap between the first part and the second part has a width W1 in the second direction, and the first part has a width W2, where 41 μm≤W1≤W2.

13. The photoelectric sensor of claim 9, wherein the at least one wall structure comprises a plurality of first wall structures and a plurality of second wall structures, wherein the plurality of first wall structures is arranged along the second direction, and the plurality of second wall structures is arranged along the first direction; and
wherein one first wall structure of the plurality of first wall structures comprises the first layer, and one second wall structure of the plurality of second wall structures comprises the first layer, wherein the first layer of the first wall structure and the first gate electrode of the photoelectric sensing element are arranged in a same layer, and the first layer of the second wall structure and the source electrode and the drain electrode of the photoelectric sensing element are arranged in a same layer.

14. The photoelectric sensor of claim 13, wherein the second wall structure is provided between two photoelectric sensing elements of the plurality of photoelectric sensing elements that are adjacent to each other in the first direction, the source electrode of one of the two photoelectric sensing elements is adjacent to the second wall structure, and the drain electrode of another one of the two photoelectric sensing elements is adjacent to the second wall structure; and
wherein a minimum distance between the second wall structure and the source electrode of the one of the two photoelectric sensing elements is equal to a minimum distance between the second wall structure and the drain electrode of the another one of the two photoelectric sensing elements.

15. The photoelectric sensor of claim 2, wherein the photoelectric sensing element further comprises a connection layer located at a side of the source electrode and the drain electrode close to the active layer; and
wherein the wall structure further comprises a fourth layer located between the first layer and the second layer, wherein the fourth layer and the connection layer are arranged in a same layer.

16. The photoelectric sensor of claim 2, wherein the first layer of the wall structure comprises a first surface away from the substrate; and
wherein the active layer of the photoelectric sensing element comprises a center part and an edge part, wherein a thickness of the center part is greater than a thickness of the edge part, the center part comprises a second surface at a side away from the substrate, and a distance H1 between the first surface and the substrate and a distance H2 between the second surface and the substrate satisfy: H1≥H2.

17. The photoelectric sensor of claim 16, wherein H1−H2≤1 μm.

18. The photoelectric sensor of claim 16, wherein the edge part comprises a third surface away from the substrate, and a distance H3 between the third surface and the substrate satisfies
$$\frac{H 1 - H 2}{H 2} < \frac{H 2 - H 3}{H 3} .$$

19. The photoelectric sensor of claim 1, wherein an included angle a between a side surface of the second layer of the wall structure and a plane of the substrate satisfies 40°≤a≤50°.

20. An electronic device, comprising:
a photoelectric sensor,
wherein the photoelectric sensor comprises:
a substrate;
a plurality of photoelectric sensing elements arranged at a side of the substrate; and
at least one wall structure,
wherein one wall structure of the at least one wall structure is located between two adjacent photoelectric sensing elements of the plurality of photoelectric sensing elements and comprises a first layer and a second layer that are stacked together, wherein the first layer is arranged at a side of the second layer away from the substrate and comprises a light-blocking material; and
wherein at least one of the first layer or the second layer of the wall structure is arranged in a same layer as at least one layer of one photoelectric sensing element of the plurality of photoelectric sensing elements.
